(19) United States
(12) Patent Application Publication
(10) Pub. No.: US 2024/0004297 A1
(43) Pub. Date: Jan. 4, 2024

(54) COMPOSITION AND METHOD FOR MANUFACTURING SEMICONDUCTOR SUBSTRATE

(71) Applicant: JSR CORPORATION, Tokyo (JP)

(72) Inventors: Tatsuya KASAI, Tokyo (JP); Ayaka Furusawa, Tokyo (JP); Kazunori Sakai, Tokyo (JP); Ryuichi Serizawa, Tokyo (JP)

(73) Assignee: JSR CORPORATION, Tokyo (JP)

(21) Appl. No.: 18/218,193

(22) Filed: Jul. 5, 2023

Related U.S. Application Data
(63) Continuation-in-part of application No. PCT/JP2021/047841, filed on Dec. 23, 2021.

(30) Foreign Application Priority Data
Jan. 7, 2021 (JP) 2021-001316

(51) Int. Cl. G03F 7/11; C08G 77/04; H01L 21/027

(52) U.S. Cl. CPC G03F 7/11; C08G 77/04; H01L 21/0274; C08G 77/80

(57) ABSTRACT

A composition includes: a solvent; and a compound including: at least one structural unit selected from the group consisting of a structural unit represented by formula (1-1) and a structural unit represented by formula (1-2); and a structural unit represented by formula (2-1). X is a monovalent organic group other than an alkoxy group, the monovalent organic group having 1 to 20 carbon atoms and having at least one fluorine atom; Y is a monovalent organic group having 1 to 20 carbon atoms, a hydroxy group, or a halogen atom; R⁰ is a substituted or unsubstituted divalent hydrocarbon group having 1 to 20 carbon atoms; R¹ is a monovalent organic group having 1 to 20 carbon atoms and having no fluorine atom, a hydroxy group, a hydrogen atom, or a halogen atom; and R² is a substituted or unsubstituted divalent hydrocarbon group having 1 to 20 carbon atoms.

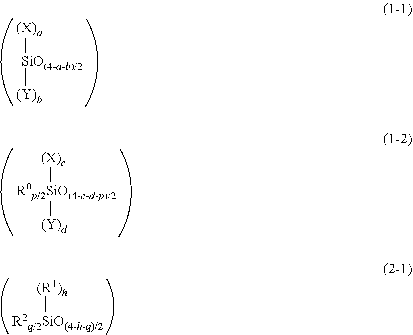

### REFERENCE TO RELATED APPLICATIONS

The present application is a continuation-in-part application of International Patent Application No. PCT/JP2021/047841 filed Dec. 23, 2021, which claims priority to Japanese Patent Application No. 2021-001316 filed Jan. 7, 2021. The contents of these applications are incorporated herein by reference in their entirety.

### BACKGROUND OF THE INVENTION

### Technical Field

The present disclosure relates to a composition and a method for manufacturing a semiconductor substrate.

### Background Art

For pattern formation in the manufacture of semiconductor substrates, for example, a multilayer resist process or the like is used in which a patterned substrate is formed by etching using, as a mask, a resist pattern obtained by exposing and developing a resist film laminated on a substrate via an organic underlayer film, a silicon-containing film, and the like (WO2012/0393337).

### SUMMARY OF THE INVENTION

According to an aspect of the present disclosure, a composition includes a solvent and a compound including: at least one structural unit selected from the group consisting of a structural unit represented by formula (1-1) and a structural unit represented by formula (1-2); and a structural unit represented by formula (2-1).

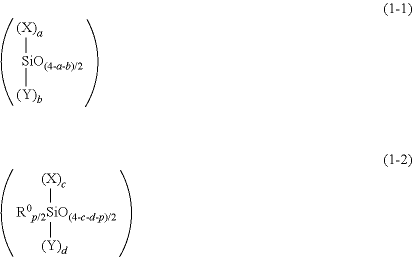

In the formula (1-1), X is a monovalent organic group other than an alkoxy group, the monovalent organic group having 1 to 20 carbon atoms and having at least one fluorine atom; a is an integer of 1 to 3; when a is 2 or more, the plurality of X's are the same or different from each other; Y is a monovalent organic group having 1 to 20 carbon atoms, a hydroxy group, or a halogen atom; b is an integer of 0 to 2; when b is 2, two Y's are the same or different from each other; and a+b is 3 or less. In the formula (1-2), X is a monovalent organic group other than an alkoxy group, the monovalent organic group having 1 to 20 carbon atoms and having at least one fluorine atom; c is an integer of 1 to 3; when c is 2 or more, the plurality of X's are the same or different from each other; Y is a monovalent organic group having 1 to 20 carbon atoms, a hydroxy group, or a halogen atom; d is an integer of 0 to 2; when d is 2, two Y's are the same or different from each other; R⁰ is a substituted or unsubstituted divalent hydrocarbon group having 1 to 20 carbon atoms and bonded to two silicon atoms; p is an integer of 1 to 3; when p is 2 or more, the plurality of R⁰'s are the same or different from each other; and c+d+p is 4 or less.

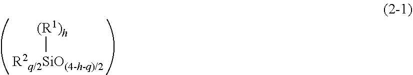

In the formula (2-1), R¹ is a monovalent organic group having 1 to 20 carbon atoms and having no fluorine atom, a hydroxy group, a hydrogen atom, or a halogen atom; h is 1 or 2; when h is 2, two R¹'s are the same or different from each other; R² is a substituted or unsubstituted divalent hydrocarbon group having 1 to 20 carbon atoms and bonded to two silicon atoms; q is an integer of 1 to 3; when q is 2 or more, the plurality of R²'s are the same or different from each other; provided that h+q is 4 or less.

According to another aspect of the present disclosure, a method for manufacturing a semiconductor substrate, includes: applying the above-described composition directly or indirectly to a substrate to form a silicon-containing film; applying a composition for forming a resist film directly or indirectly to the silicon-containing film to form a resist film; exposing the resist film to radiation; and developing the exposed resist film to form a resist pattern.

### DETAILED DESCRIPTION

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

In recent years, highly enhanced integration of semiconductor devices has further advanced, and exposure light to be used tends to have a shorter wavelength, as from a KrF excimer laser beam (248 nm) or an ArF excimer laser beam (193 nm) to an extreme ultraviolet ray (13.5 nm; hereinafter also referred to as “EUV”).

While the line width of a resist pattern formed through exposure to extreme ultraviolet rays and development is being miniaturized to a level of 20 nm or less, a silicon-containing film is required to have a collapse inhibition property of a resist pattern. In addition, in a process of removing a silicon-containing film in a manufacturing process of a semiconductor substrate or the like, the silicon-containing film is required to be easily removed with a basic liquid such as basic hydrogen peroxide water while controlling damage to the substrate.

The present invention relates to, in one embodiment, a composition including:

a compound having at least one structural unit selected from the group consisting of a structural unit represented by formula (1-1) and a structural unit represented by formula (1-2) (hereinafter also referred to as “structural unit (I)”) and a structural unit represented by formula (2-1) (hereinafter also referred to as “structural unit (II)”) (the compound is hereinafter also referred to as “compound [A]”), and

a solvent (hereinafter also referred to as “solvent [B]”),

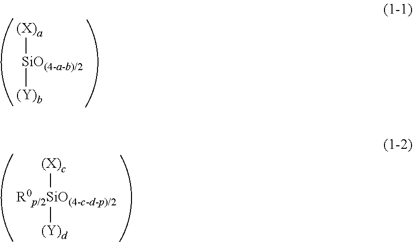

in the formula (1-1), X is a monovalent organic group having 1 to 20 carbon atoms and having at least one fluorine atom (excluding cases where X is an alkoxy group); a is an integer of 1 to 3; when a is 2 or more, the plurality of X's are the same or different from each other; Y is a monovalent organic group having 1 to 20 carbon atoms, a hydroxy group, or a halogen atom; b is an integer of 0 to 2; when b is 2, two Y's are the same or different from each other; and a+b is 3 or less,

in the formula (1-2), X is a monovalent organic group having 1 to 20 carbon atoms and having at least one fluorine atom (excluding cases where X is an alkoxy group); c is an integer of 1 to 3; when c is 2 or more, the plurality of X's are the same or different from each other; Y is a monovalent organic group having 1 to 20 carbon atoms, a hydroxy group, or a halogen atom; d is an integer of 0 to 2; when d is 2, two Y's are the same or different from each other; R⁰ is a substituted or unsubstituted divalent hydrocarbon group having 1 to 20 carbon atoms and bonded to two silicon atoms; p is an integer of 1 to 3; when p is 2 or more, the plurality of R⁰'s are the same or different from each other; and c+d+p is 4 or less,

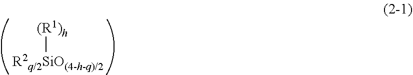

in the formula (2-1), R¹ is a monovalent organic group having 1 to 20 carbon atoms (containing no fluorine atom), a hydroxy group, a hydrogen atom, or a halogen atom; h is 1 or 2; when h is 2, two R¹'s are the same or different from each other; R² is a substituted or unsubstituted divalent hydrocarbon group having 1 to 20 carbon atoms and bonded to two silicon atoms; q is an integer of 1 to 3; when q is 2 or more, the plurality of R²'s are the same or different from each other; and h+q is 4 or less.

The composition contains a compound [A] including a structural unit (I) having a fluorine atom and a structural unit (II) capable of forming a carbosilane skeleton. Using this composition, it is possible to form a silicon-containing film capable of exhibiting superior resist pattern collapse inhibition property and film removability. The reason for this is not clear, but can be expected as follows. During the alkali development of the exposed resist film, in the unexposed portion, adhesion to the upper resist film is maintained by the highly hydrophobic silicon-containing film due to the fluorine atom of the structural unit (I) and the carbosilane skeleton derived from the structural unit (II), and as a result, collapse of the resist pattern is suppressed. In addition, since the silicon-containing film formed of the composition includes the structural unit (I) having a fluorine atom, it is presumed that the silicon-containing film resulting from oxygen-based gas etching acquires a reduced film density, so that a basic liquid such as basic hydrogen peroxide water easily permeates the silicon-containing film, accordingly enabling easy removal with a basic liquid such as basic hydrogen peroxide water.

As used herein, “organic group” means a group containing at least one carbon atom, and “carbon number” means the number of carbon atoms constituting the group.

Another embodiment of the present invention relates to a method for manufacturing a semiconductor substrate, including

directly or indirectly applying the composition according to claim 1 to a substrate to form a silicon-containing film;

directly or indirectly applying a composition for forming a resist film to the silicon-containing film to form the resist film; and

exposing the resist film to radiation;

developing the exposed resist film to form a resist pattern.

In the manufacturing method, the composition is used for forming a silicon-containing film as an underlayer of a resist film, and superior pattern collapse inhibition property and film removability can be exhibited, so that a high-quality semiconductor substrate can be efficiently manufactured.

Hereinafter, a composition and a method for manufacturing a semiconductor substrate according to embodiments of the present invention will be described in detail.

### <<Composition>>

The composition contains a compound [A] and a solvent [B]. The composition may further contain other optional components as long as the effects of the present invention are not impaired.

As the resist film to be alkali-developed, a positive resist film is preferable, and a positive resist film for exposure with ArF excimer laser light (ArF exposure) or extreme ultraviolet (EUV) (EUV exposure) is more preferable. In other words, the composition is suitably used for forming an underlayer film of an alkali-developable resist film for ArF exposure or EUV exposure. Each component contained in the composition will be described below.

### <Compound [A]>

The compound [A] has a structural unit (I) and a structural unit (II). In the following, each structural unit of the compound [A] will be described.

### (Structural Unit (I))

The structural unit (I) is at least one selected from the group consisting of a structural unit represented by formula (1-1) and a structural unit represented by formula (1-2).

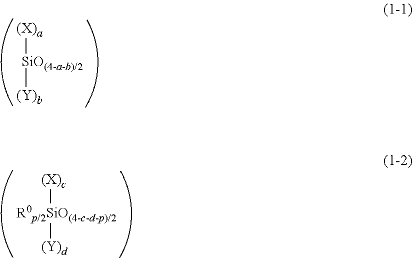

In the formula (1-1), X is a monovalent organic group having 1 to 20 carbon atoms and having at least one fluorine atom (excluding cases where X is an alkoxy group). a is an integer of 1 to 3; when a is 2 or more, the plurality of X's are the same or different from each other; Y is a monovalent organic group having 1 to 20 carbon atoms, a hydroxy group, or a halogen atom; b is an integer of 0 to 2; when b is 2, two Y's are the same or different from each other; and a+b is 3 or less,

In the formula (1-2), X is a monovalent organic group having 1 to 20 carbon atoms and having at least one fluorine atom (excluding cases where X is an alkoxy group); c is an integer of 1 to 3; when c is 2 or more, the plurality of X's are the same or different from each other; Y is a monovalent organic group having 1 to 20 carbon atoms, a hydroxy group, or a halogen atom; d is an integer of 0 to 2; when d is 2, two Y's are the same or different from each other; R⁰ is a substituted or unsubstituted divalent hydrocarbon group having 1 to 20 carbon atoms and bonded to two silicon atoms; p is an integer of 1 to 3; when p is 2 or more, the plurality of R⁰'s are the same or different from each other; and It is noted that c+d+p is 4 or less.

Examples of the monovalent organic group having 1 to 20 carbon atoms and having at least one fluorine atom represented by X in the formula (1-1) and the formula (1-2) include a group in which at least one hydrogen atom of a monovalent organic group having 1 to 20 carbon atoms is substituted with a fluorine atom. It is noted that an alkoxy group is excluded as X. Examples of the monovalent organic group having 1 to 20 carbon atoms include a monovalent hydrocarbon group having 1 to 20 carbon atoms, a group containing a divalent heteroatom-containing liking group between carbon-carbon bonds or at the end of the hydrocarbon group (hereinafter, also referred to as a “group (α)”), a group obtained by substituting a part or all of hydrogen atoms of the hydrocarbon group or the group (α) with a monovalent heteroatom-containing substituent (hereinafter, also referred to as a “group (β)”), and a group obtained by combining the hydrocarbon group, the group (α) or the group (β) with a divalent heteroatom-containing linking group (hereinafter, also referred to as a “group (γ)”).

As used herein, the “hydrocarbon group” includes a chain hydrocarbon group, an alicyclic hydrocarbon group, and an aromatic hydrocarbon group. The “hydrocarbon group” may be a saturated hydrocarbon group or an unsaturated hydrocarbon group. The “chain hydrocarbon group” means a hydrocarbon group that does not include a cyclic structure and is composed only of a chain structure, and includes both a linear hydrocarbon group and a branched hydrocarbon group. The “alicyclic hydrocarbon group” means a hydrocarbon group that includes only an alicyclic structure as a ring structure and does not include an aromatic ring structure, and includes both a monocyclic alicyclic hydrocarbon group and a polycyclic alicyclic hydrocarbon group. However, it is not necessary for the alicyclic hydrocarbon group to be composed only of an alicyclic structure, and the alicyclic hydrocarbon group may include a chain structure in a part thereof. The “aromatic hydrocarbon group” means a hydrocarbon group that includes an aromatic ring structure as a ring structure. However, it is not necessary for the aromatic hydrocarbon group to be composed only of an aromatic ring structure, and the aromatic hydrocarbon group may include a chain structure or an alicyclic structure in a part thereof.

Examples of the monovalent hydrocarbon group having 1 to 20 carbon atoms include monovalent chain hydrocarbon groups having 1 to 20 carbon atoms, monovalent alicyclic hydrocarbon groups having 3 to 20 carbon atoms, monovalent aromatic hydrocarbon groups having 6 to 20 carbon atoms or a combination of these groups.

Examples of monovalent chain hydrocarbon groups having 1 to 20 carbon atoms include alkyl groups such as a methyl group, an ethyl group, a n-propyl group, an i-propyl group, a n-butyl group, a sec-butyl group, an iso-butyl group, a tert-butyl group, alkenyl groups such as an ethenyl group, a propenyl group and a butenyl group, and alkynyl groups such as an ethynyl group, a propynyl group and a butynyl group.

Examples of monovalent alicyclic hydrocarbon groups having 3 to 20 carbon atoms include monocyclic saturated alicyclic hydrocarbon groups such as cyclopentyl group and cyclohexyl group, polycyclic alicyclic saturated hydrocarbon groups such as a norbornyl group, an adamantyl group, a tricyclodecyl group, a tetracyclododecyl group, monocyclic alicyclic unsaturated hydrocarbon groups such as a cyclopentenyl group and a cyclohexenyl group, polycyclic alicyclic unsaturated hydrocarbon groups such as a norbornenyl group, a tricyclodecenyl group, a tetracyclododesenyl group.

Examples of monovalent aromatic hydrocarbon groups having 6 to 20 carbon atoms include aryl groups such as a phenyl group, a tolyl group, a xylyl group, a naphthyl group and an anthryl group, aralkyl groups such as a benzyl group, a phenethyl group, a naphthylmethyl group and an anthrylmethyl group.

Examples of the heteroatoms that constitute the divalent heteroatom-containing linking group and the monovalent heteroatom-containing substituent include an oxygen atom, a nitrogen atom, a sulfur atom, a phosphorus atom, a silicon atom, and halogen atoms. Examples of the halogen atoms other than a fluorine atom include a chlorine atom, a bromine atom, and an iodine atom.

Examples of the divalent heteroatom-containing liking groups include, for example, —O—, —C(═O)—, —S—, —C(═S)—, —NR′—, —SO₂—, or combinations of two or more of these and the like. R′ is a hydrogen atom or a monovalent hydrocarbon group.

As the monovalent heteroatom-containing substituent, at least a fluorine atom is contained, and other examples thereof include halogen atom other than a fluorine atom, a hydroxy group, a carboxy group, a cyano group, an amino group, and a sulfanyl group.

In the formula (1-1) and the formula (1-2), a and c are each independently preferably 1 or 2, and more preferably 1.

The monovalent organic group having 1 to 20 carbon atoms represented by Y in the formula (1-1) and the formula (1-2) may be, for example, the monovalent organic group having 1 to 20 carbon atoms for X described above. It is noted that Y includes an alkoxy group, but does not necessarily have a fluorine atom.

Examples of the halogen atom represented by Y include a fluorine atom, a chlorine atom, a bromine atom, and an iodine atom.

In the case that Y is present, Y is preferably a monovalent chain hydrocarbon group, a monovalent aromatic hydrocarbon group, or a monovalent group in which a part or all of the hydrogen atoms of the monovalent hydrocarbon group are replaced with a monovalent heteroatom-containing substituent, more preferably an alkyl group or an aryl group, and further preferably a methyl group, an ethyl group or a phenyl group.

In the formula (1-1) and the formula (1-2), b and d are each independently preferably 0 or 1, and more preferably 0.

Examples of the substituted or unsubstituted divalent hydrocarbon group having 1 to 20 carbon atoms and bonded to two silicon atoms represented by R⁰ in the formula (1-2) include a substituted or unsubstituted divalent chain hydrocarbon group having 1 to 20 carbon atoms, a substituted or unsubstituted divalent aliphatic cyclic hydrocarbon group having 3 to 20 carbon atoms, and a substituted or unsubstituted divalent aromatic hydrocarbon group having 6 to 20 carbon atoms.

Examples of the unsubstituted divalent chain hydrocarbon group having 1 to 20 carbon atoms include chain saturated hydrocarbon groups such as a methanediyl group and an ethanediyl group, and chain unsaturated hydrocarbon groups such as an ethenediyl group and a propenediyl group.

Examples of the unsubstituted divalent aliphatic cyclic hydrocarbon group having 3 to 20 carbon atoms include monocyclic saturated hydrocarbon groups such as a cyclobutanediyl group, monocyclic unsaturated hydrocarbon groups such as a cyclobutenediyl group, polycyclic saturated hydrocarbon groups such as a bicyclo[2.2.1]heptanediyl group, and polycyclic unsaturated hydrocarbon groups such as a bicyclo[2.2.1]heptenediyl group.

Examples of the unsubstituted divalent aromatic hydrocarbon group having 6 to 20 carbon atoms include a phenylene group, a biphenylene group, a phenylene ethylene group, and a naphthylene group.

Examples of the substituent in the substituted divalent hydrocarbon group having 1 to 20 carbon atoms represented by R⁰ include a halogen atom, a hydroxy group, a cyano group, a nitro group, an alkoxy group, an acyl group, and an acyloxy group.

As R⁰, an unsubstituted chain saturated hydrocarbon group or an unsubstituted aromatic hydrocarbon group is preferable, and a methanediyl group, an ethanediyl group, or a phenylene group is more preferable.

In the formula (1-1) and the formula (1-2), p is preferably 2 or 3.

X in the formula (1-1) and the formula (1-2) is preferably represented by formula (3).

*-L¹-Z-L²-R^{f} (3)

In the formula (3), L¹ and L² are each independently a single bond or a substituted or unsubstituted divalent hydrocarbon group having 1 to 10 carbon atoms. Z is a single bond, an oxygen atom or a sulfur atom. R^{f} is a fluorine atom or a monovalent fluorinated hydrocarbon group having 1 to 10 carbon atoms. * is a bond with the silicon atoms in the formula (1-1) and the formula (1-2).

Examples of the substituted or unsubstituted divalent hydrocarbon groups having 1 to 10 carbon atoms represented by L¹ and L² in the above formula (3) include groups obtained by removing one hydrogen atom from groups corresponding to 1 to 10 carbon atoms among the monovalent hydrocarbon groups having 1 to 20 carbon atoms recited for X in the above formula (1-1). L¹ and L² are each independently preferably a divalent chain hydrocarbon group having 1 to 10 carbon atoms or a divalent aromatic hydrocarbon group having 1 to 10 carbon atoms.

Examples of the monovalent fluorinated hydrocarbon group having 1 to 10 carbon atoms represented by R^{f} in the formula (3) include monovalent fluorinated chain hydrocarbon groups having 1 to 10 carbon atoms, monovalent fluorinated alicyclic hydrocarbon groups having 3 to 10 carbon atoms, monovalent fluorinated aromatic hydrocarbon groups having 6 to 10 carbon atoms, and combinations thereof.

Examples of the monovalent fluorinated chain hydrocarbon group having 1 to 10 carbon atoms include:

fluorinated alkyl groups such as a trifluoromethyl group, a 2,2,2-trifluoroethyl group, a pentafluoroethyl group, a 2,2,3,3,3-pentafluoropropyl group, a 1,1,1,3,3,3-hexafluoropropyl group, a heptafluoro-n-propyl group, a heptafluoro-i-propyl group, a nonafluoro-n-butyl group, a nonafluoro-i-butyl group, a nonafluoro-t-butyl group, a 2,2,3,3,4,4,5,5-octafluoro-n-pentyl group, a tridecafluoro-n-hexyl group, and a 5,5,5-trifluoro-1,1-diethylpentyl group;

fluorinated alkenyl groups such as a trifluoroethenyl group and a pentafluoropropenyl group; and

fluorinated alkynyl groups such as a fluoroethynyl group and a trifluoropropynyl group.

Examples of the monovalent fluorinated alicyclic hydrocarbon group having 3 to 10 carbon atoms include:

fluorinated cycloalkyl groups such as a fluorocyclopentyl group, a difluorocyclopentyl group, a nonafluorocyclopentyl group, a fluorocyclohexyl group, a difluorocyclohexyl group, an undecafluorocyclohexylmethyl group, a fluoronorbornyl group, a fluoroadamantyl group, a fluorobornyl group, a fluoroisobornyl group, and a fluorotricyclodecyl group; and

fluorinated cycloalkenyl groups such as a fluorocyclopentenyl group and a nonafluorocyclohexenyl group.

Examples of the monovalent fluorinated aromatic hydrocarbon group having 6 to 10 carbon atoms include:

fluorinated aryl groups such as a 3-fluorophenyl group, a 4-fluorophenyl group, a 3,5-difluorophenyl group, a 3-trifluoromethylphenyl group, and a 3,5-bis(trifluoromethyl)phenyl group.

As the fluorinated hydrocarbon group, the monovalent fluorinated chain hydrocarbon group having 1 to 10 carbon atoms or the monovalent fluorinated aromatic hydrocarbon group having 6 to 10 carbon atoms is preferable, a monovalent fluorinated alkyl group having 1 to 10 carbon atoms or a monovalent fluorinated aryl group having 6 to 10 carbon atoms is more preferable, and a perfluoroalkyl group having 1 to 6 carbon atoms or a fluorinated phenyl group is still more preferable.

Examples of X represented by the formula (3) include a structure represented by formula.

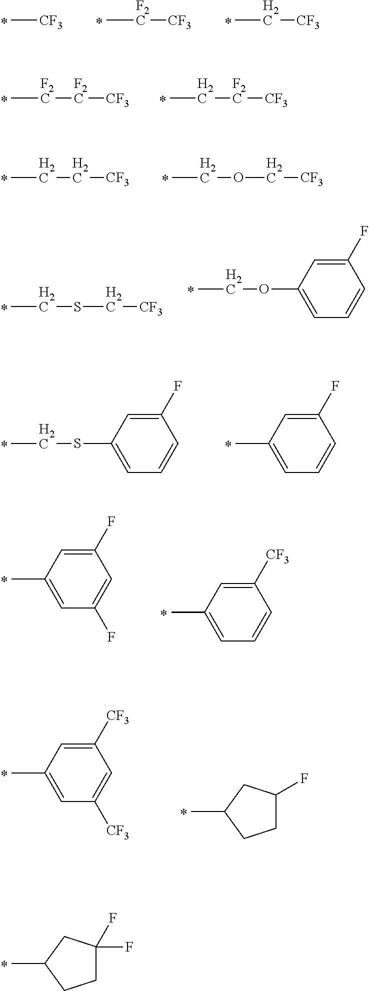

In the above formula, * is a bond with the silicon atoms in the formula (1-1) and the formula (1-2).

The lower limit of the content ratio of the structural unit (I) (when a plurality of types of structural unit (I) are contained, a total content ratio is taken) is preferably 1 mol %, more preferably 2 mol %, still more preferably 3 mol %, and particularly preferably 5 mol % based on all structural units constituting the compound [A]. The upper limit of the content ratio is preferably 50 mol %, more preferably 40 mol %, still more preferably 35 mol %, and particularly preferably 30 mol %. By setting the content ratio of the structural unit (I) within the above range, the pattern collapse inhibition property and the film removability can be further improved.

### (Structural Unit (II))

The structural unit (II) is a structural unit represented by formula (2-1).

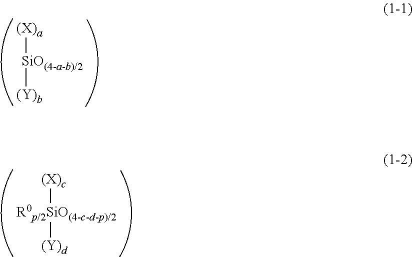

In the formula (2-1), R¹ is a monovalent organic group having 1 to 20 carbon atoms (containing no fluorine atom), a hydroxy group, a hydrogen atom, or a halogen atom. h is 1 or 2; when h is 2, two R¹'s are the same or different from each other; R² is a substituted or unsubstituted divalent hydrocarbon group having 1 to 20 carbon atoms and bonded to two silicon atoms; q is an integer of 1 to 3; when q is 2 or more, the plurality of R²'s are the same or different from each other; and It is noted that h+q is 4 or less.

Examples of the monovalent organic group having 1 to 20 carbon atoms represented by R¹ in the formula (2-1) include groups the same as those recited as examples of the monovalent organic group having 1 to 20 carbon atoms of Y in the formula (1-1) except that no fluorine atom is contained.

R¹ is preferably a hydrogen atom, a monovalent chain hydrocarbon group, a monovalent aromatic hydrocarbon group, or a monovalent group in which a part or all of the hydrogen atoms of the monovalent hydrocarbon group are replaced with a monovalent heteroatom-containing group, more preferably a hydrogen atom, an alkyl group or an aryl group, and further preferably a hydrogen atom, a methyl group, an ethyl group, or a phenyl group.

Examples of the substituted or unsubstituted divalent hydrocarbon group having 1 to 20 carbon atoms and bonded to two silicon atoms represented by R² include groups the same as those recited as examples of the substituted or unsubstituted divalent hydrocarbon group having 1 to 20 carbon atoms and bonded to two silicon atoms of R⁰ in the formula (1-2).

As R², an unsubstituted chain saturated hydrocarbon group or an unsubstituted aromatic hydrocarbon group is preferable, and a methanediyl group, an ethanediyl group, or a phenylene group is more preferable.

h is preferably 1.

q is preferably 2 or 3.

The lower limit of the content ratio of the structural unit (II) (when a plurality of types of structural unit (II) are contained, a total content ratio is taken) is preferably 50 mol %, more preferably 60 mol %, still more preferably 65 mol %, and particularly preferably 70 mol % based on all structural units constituting the compound [A]. The upper limit of the content ratio is preferably 99 mol %, more preferably 98 mol %, still more preferably 97 mol %, and particularly preferably 95 mol %.

The lower limit of the content ratio of the compound [A] is preferably 1% by mass, more preferably 2% by mass, and still more preferably 4% by mass based on all components of the composition excluding the solvent [B]. The upper limit of the content ratio is preferably 30% by mass, more preferably 20% by mass, and still more preferably 10% by mass.

The compound [A] is preferably in the form of a polymer. The term “polymer” refers to a compound having two or more structural units, and when two or more identical structural units are consecutive in a polymer, the structural units are also referred to as “repeating units”. When the compound [A] is in the form of a polymer, the lower limit of the polystyrene-equivalent weight-average molecular weight (Mw) of the compound [A] determined by gel permeation chromatography (GPC) is preferably 800, more preferably 1,000, still more preferably 1,300, and particularly preferably 1,500. The upper limit of Mw is preferably 50,000, more preferably 20,000, still more preferably 7,000, and particularly preferably 3,000. The Mw of the compound [A] is measured as described in Examples.

### <Synthesis of Compound [A]>

The compound [A] is obtained, for example, through hydrolysis condensation of a polycarbosilane having the structural units (I) and (II), hydrolysis condensation of a polycarbosilane having the structural units (I) and (II) with a silane compound that affords the structural unit (I), or hydrolysis condensation of a polycarbosilane having the structural unit (II) with a silane compound that affords the structural unit (I). At the time of hydrolysis condensation, another silane compound or the like may be added, as necessary. The hydrolysis condensation can be performed by performing hydrolysis condensation in a solvent such as diisopropyl ether in the presence of water and a catalyst such as oxalic acid, and preferably purifying a solution containing the generated hydrolysis condensate through solvent substitution or the like in the presence of a dehydrating agent such as ortho ester or molecular sieve. It is considered that each hydrolyzable silane monomer is incorporated into the compound [A] through a hydrolysis condensation reaction or the like regardless of the type of the hydrolyzable silane monomer. The content ratio of the structural units (I) and (II) and other structural units in the compound [A] synthesized is usually equivalent to the ratio of the amounts of the respective monomer compounds used in the synthesis reaction.

### <Solvent [B]>

Examples of the solvent [B] include alcohol-based solvents, ketone-based solvents, ether-based solvents, ester-based solvents, nitrogen-containing solvents, and water. The solvent [B] may be used singly or two or more kinds thereof may be used in combination.

Examples of alcohol solvents include monoalcohol solvents such as methanol, ethanol, n-propanol, iso-propanol, n-butanol and iso-butanol, polyhydric alcohol solvents such as ethylene glycol, 1,2-propylene glycol, diethylene glycol and dipropylene glycol.

Examples of ketone solvents include acetone, methyl ethyl ketone, methyl-n-propyl ketone, methyl-iso-butyl ketone, cyclohexanone and the like.

Examples of ether solvents include ethyl ether, iso-propyl ether, ethylene glycol dibutyl ether, diethylene glycol monomethyl ether, diethylene glycol monoethyl ether, diethylene glycol diethyl ether, propylene glycol monomethyl ether, propylene glycol monoethyl ether, propylene glycol monopropyl ether, tetrahydrofuran and the like.

Examples of ester solvents include ethyl acetate, γ-butyrolactone, n-butyl acetate, ethylene glycol monomethyl ether acetate, ethylene glycol monoethyl ether acetate, diethylene glycol monomethyl ether acetate, diethylene glycol monoethyl ether acetate, propylene glycol monomethyl ether acetate, propylene glycol monoethyl ether acetate, dipropylene glycol monomethyl ether acetate, dipropylene glycol monoethyl ether acetate, ethyl propionate, n-butyl propionate, methyl lactate, ethyl lactate and the like.

Examples of nitrogen-containing solvents include N,N-dimethylformamide, N,N-dimethylacetamide, N-methylpyrrolidone, and the like.

Among these, ether-based solvents or ester-based solvents are preferable, and ether-based solvents or ester-based solvents having a glycol structure are more preferable because of their excellent film-forming properties.

Examples of ether solvents and ester solvents having a glycol structure include propylene glycol monomethyl ether, propylene glycol monoethyl ether, propylene glycol monopropyl ether, propylene glycol monomethyl ether acetate, propylene glycol monoethyl ether acetate, and propylene glycol monopropyl ether acetate and the like. Among these, propylene glycol monomethyl ether acetate or propylene glycol monoethyl ether is preferable.

The content ratio of the ether-based solvent having a glycol structure and the ester-based solvent in the solvent [B] is preferably 20% by mass or more, more preferably 60% by mass or more, still more preferably 90% by mass or more, and particularly preferably 100% by mass.

The lower limit of the content ratio of the solvent [B] in the composition is preferably 50% by mass, more preferably 80% by mass, still more preferably 90% by mass, and particularly preferably 95% by mass. The upper limit of the content ratio is preferably 99.9% by mass, and more preferably 99% by mass.

### <Other Optional Components>

Examples of other optional components include acid generators, basic compounds (including base generators), ortho esters, radical generators, surfactants, colloidal silica, colloidal alumina, and organic polymers. The other optional components may be used singly or two or more kinds thereof may be used in combination.

### (Acid Generator)

The acid generator is a component that generates an acid through exposure to light or heating. When the composition contains an acid generator, the condensation reaction of the compound [A] can be promoted even at a relatively low temperature (including normal temperature).

Examples of the acid generator that generates an acid through exposure to light (hereinafter also referred to as “photo-acid generator”) include the acid generators described in paragraphs [0077] to[0081] in JP-A-2004-168748, and triphenylsulfonium trifluoromethanesulfonate.

Examples of the acid generator that generates an acid through heating (hereinafter also referred to as “thermal acid generator”) include onium salt-based acid generators recited as examples of photo-acid generators in the above-cited Patent Document, 2,4,4,6-tetrabromocyclohexadienone, benzoin tosylate, 2-nitrobenzyl tosylate, and alkyl sulfonates.

When the composition comprises an acid generator, the lower limit of the content of the acid generator is preferably 0.001 parts by mass, and more preferably 0.01 parts by mass based on 100 parts by mass of the compound [A]. The upper limit of the content of the acid generator is preferably 5 parts by mass, and more preferably 1 part by mass based on 100 parts by mass of the compound [A].

### (Basic Compound)

The basic compound promotes a curing reaction of the composition, and as a result, enhance the strength or the like of a film to be formed. In addition, the basic compound improves the peelability of the film with an acidic solution. Examples of the basic compound include a compound having a basic amino group, and a base generator that generates a compound having a basic amino group by the action of an acid or the action of heat. Examples of the compound having a basic amino group include amine compounds. Examples of the base generator include an amide group-containing compound, a urea compound, and a nitrogen-containing heterocyclic compound. Examples of the amine compound, the amide group-containing compound, the urea compound, and the nitrogen-containing heterocyclic compound include compounds described in paragraphs[0079] to[0082] of JP-A-2016-27370.

When the composition comprises a basic compound, the lower limit of the content of the basic compound is preferably 0.001 parts by mass, and more preferably 0.01 parts by mass, based on 100 parts by mass of the compound [A]. The upper limit of the content is preferably 5 parts by mass, and more preferably 1 part by mass.

### (Ortho Ester)

The ortho ester is an ester form of an orthocarboxylic acid. The ortho ester reacts with water to afford a carboxylate ester or the like. Examples of the ortho ester include orthoformate esters such as methyl orthoformate, ethyl orthoformate, and propyl orthoformate, orthoacetate esters such as methyl orthoacetate, ethyl orthoacetate, and propyl orthoacetate, and orthopropionate esters such as methyl orthopropionate, ethyl orthopropionate, and propyl orthopropionate. Among them, an orthoformate is preferable, and trimethyl orthoformate is more preferable.

When the composition comprises an ortho ester, the lower limit of the content of the ortho ester is preferably 0.1 parts by mass, more preferably 0.5 parts by mass, and still more preferably 1 part by mass, based on 100 parts by mass of the compound [A]. The upper limit of the content is preferably 30% by mass, more preferably 20% by mass, and still more preferably 10% by mass.

### <Method for Preparing Composition>

The method for preparing the composition is not particularly limited, and for example, the composition can be prepared by mixing a solution of the compound [A], the solvent [B], and other optional components which are used as necessary in a prescribed ratio, and then filtering the resulting mixed solution through a filter having a pore size of 0.2 μm or less.

### <<Method for Manufacturing Semiconductor Substrate>>

A method for manufacturing a semiconductor substrate according to the present embodiment includes: directly or indirectly applying the composition to a substrate to form a silicon-containing film (hereinafter, also referred to as a “silicon-containing film forming step”); directly or indirectly applying a composition for forming a resist film to the silicon-containing film to form the resist film (hereinafter, also referred to as a “resist film forming step”); exposing the resist film to radiation (hereinafter, also referred to as an “exposing step”); developing the exposed resist film to form a resist pattern (hereinafter, also referred to as a “developing step”).

The method for manufacturing a semiconductor substrate may further include, if necessary, directly or indirectly forming an organic underlayer film on the substrate (hereinafter, also referred to as an “organic underlayer film forming step”) before the silicon-containing film forming step.

Further, the method for manufacturing a semiconductor substrate may further include, after the developing step, etching the silicon-containing film using the resist pattern as a mask to form a silicon-containing film pattern (hereinafter, also referred to as a “silicon-containing film pattern forming step”), performing etching using the silicon-containing film pattern as a mask (hereinafter, also referred to as an “etching step”), and removing the silicon-containing film pattern by a basic liquid (hereinafter, also referred to as a “removing step”).

According to the method for manufacturing a semiconductor substrate, it is possible to form a silicon-containing film superior in pattern collapse inhibition property and film removability by using the above-described composition in the silicon-containing film forming step.

Hereinbelow, each of the steps of the method for manufacturing a semiconductor substrate will be described with reference to a case where the method includes the organic underlayer film forming step before the silicon-containing film forming step and the silicon-containing film pattern forming step, the etching step, and the removing step after the developing step.

### [Organic Underlayer Film Forming Step]

In this step, an organic underlayer film is formed directly or indirectly on the substrate before the silicon-containing film forming step. This step is an arbitrary step. Through this step, an organic underlayer film is formed directly or indirectly on the substrate.

The organic underlayer film can be formed by applying a composition for forming an organic underlayer film. The method of forming the organic underlayer film by applying the composition for forming an organic underlayer film may be, for example, a method in which a coating film formed by directly or indirectly applying the composition for forming an organic underlayer film to a substrate is cured by heating or exposure. As the composition for forming an organic underlayer film, for example, “HM8006” manufactured by JSR Corporation can be used. Various conditions for heating or exposure can be appropriately determined according to the type of the composition for forming an organic underlayer film to be used.

Examples of a case where an organic underlayer film is indirectly formed on a substrate include a case where an organic underlayer film is formed on a low dielectric insulating film formed on a substrate.

### [Silicon-Containing Film Forming Step]

In this step, the composition is directly or indirectly applied to the substrate to form a silicon-containing film. By this step, a coating film of the composition is formed directly or indirectly on the substrate, and the coating film is usually cured by heating to form a silicon-containing film as a resist underlayer film.

Examples of substrates include insulating films such as silicon oxide, silicon nitride, silicon oxynitride and polysiloxane, and resin substrates. Also, the substrate may be a substrate having patterning such as a wiring groove (trench), a plug groove (vias) and the like.

The method of applying the composition is not particularly limited, and examples thereof include a spin coating method.

Examples of the case of indirectly applying the composition to the substrate include, for example, the case of applying the composition onto another film formed on the substrate. Other films formed on the substrate include, for example, an organic underlayer film which is formed by the organic underlayer film forming step described above, an antireflection film, a low dielectric insulating film, and the like.

When the coating film is heated, the atmosphere is not particularly limited, and examples thereof include air atmosphere, nitrogen atmosphere, and the like. Heating of the coating film is usually performed in the air atmosphere. Various conditions such as the heating temperature and the heating time when the coating film is heated can be appropriately determined. The lower limit of the heating temperature is preferably 90° C., more preferably 150° C., and even more preferably 200° C. The upper limit of the heating temperature is preferably 550° C., more preferably 450° C., and even more preferably 300° C. The lower limit of the heating time is preferably 15 seconds, more preferably 30 seconds. The upper limit of the heating time is preferably 1,200 seconds, more preferably 600 seconds.

When the composition contains an acid generator, and the acid generator is a radiation-sensitive acid generator, the formation of the silicon-containing film can be accelerated by combining heating and exposure. Radiation used for exposure includes, for example, the same radiation as exemplified in the exposing step described later.

The lower limit of the average thickness of the silicon-containing film formed by this step is preferably 1 nm, more preferably 3 nm, and even more preferably 5 nm. The upper limit of the average thickness is preferably 500 nm, more preferably 300 nm, and even more preferably 200 nm. The method for measuring the average thickness of the silicon-containing film is described in Examples.

### [Resist Film Forming Step]

In this step, a composition for forming a resist film is directly or indirectly applied to the silicon-containing film to form the resist film. Through this step, a resist film is formed directly or indirectly on the silicon-containing film.

The method of applying the composition for forming a resist film is not particularly limited, and examples thereof include a spin coating method.

To explain this step in more detail, for example, after applying a resist composition so that the formed resist film has a predetermined thickness, pre-baking (hereinafter also referred to as “PB”) is performed to volatilize the solvent to form a resist film.

The PB temperature and PB time can be appropriately determined according to the type of resist film forming composition used. The lower limit of the PB temperature is preferably 30° C., more preferably 50° C. The upper limit of the PB temperature is preferably 200° C., more preferably 150° C. The lower limit of the PB time is preferably 10 seconds, more preferably 30 seconds. The upper limit of the PB time is preferably 600 seconds, more preferably 300 seconds.

As the composition for forming a resist film used in this step, a so-called positive-type composition for forming a resist film for alkali development is preferably used. Such a composition for forming a resist film is preferably a positive-type composition for forming a resist film containing, for example, a resin having an acid-dissociable group and a radiation-sensitive acid generator and intended for exposure to ArF excimer laser light (for ArF exposure) or exposure to extreme ultraviolet (for EUV exposure).

### [Exposing Step]

In this step, the resist film formed by the resist film forming step is exposed to radiation. This step causes a difference in solubility in an alkaline solution, which is a developer, between an exposed portion and an unexposed portion of the resist film. More specifically, the solubility of the exposed portion of the resist film to an alkaline solution increases.

The radiation used for exposure can be appropriately selected according to the type of a composition for forming a resist film used. Examples thereof include electromagnetic waves such as visible light, ultraviolet rays, far ultraviolet rays, X-rays and γ-rays, and particle beams such as electron beams, molecular beams and ion beams. Among these, far ultraviolet rays are preferable, and KrF excimer laser light (wavelength 248 nm), ArF excimer laser light (wavelength 193 nm), F₂ excimer laser light (wavelength 157 nm), Kr₂ excimer laser light (wavelength 147 nm), ArKr excimer laser light (wavelength of 134 nm) or extreme ultraviolet rays (wavelength of 13.5 nm, etc., also referred to as “EUV”) are more preferred, and ArF excimer laser light or EUV is even more preferred. Also, the exposure conditions can be appropriately determined according to the type of the composition for forming a resist film to be used.

In addition, in this step, post-exposure bake (hereinafter also referred to as “PEB”) can be performed in order to improve the performance of the resist film such as resolution, pattern profile, developability, etc. after the exposure. The PEB temperature and PEB time can be appropriately determined according to the type of composition for forming a resist film used. The lower limit of the PEB temperature is preferably 50° C., more preferably 70° C. The upper limit of the PEB temperature is preferably 200° C., more preferably 150° C. The lower limit of the PEB time is preferably 10 seconds, more preferably 30 seconds. The upper limit of the PEB time is preferably 600 seconds, more preferably 300 seconds.

### [Developing Step]

In this step, the exposed resist film is developed. The development of the exposed resist film is preferably alkali development. Due to the above exposing step, the solubility in the alkaline solution, which is the developer, differs between the exposed area and the unexposed area in the resist film. A resist pattern is formed by removing the exposed portion, which is relatively soluble in an alkaline solution, by carrying out alkali development.

The developer used in alkaline development is not particularly limited, and known developers can be used. Examples of developer for alkaline development include an alkaline aqueous solution containing at least one of dissolved alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, 1,5-diazabicyclo-[4.3.0]-5-nonene, and the like. Among these, a TMAH aqueous solution is preferable, and a 2.38% by mass TMAH aqueous solution is more preferable.

Examples of a developer used for organic solvent development include the same developer as those exemplified as the solvent for the composition described above.

In this step, washing and/or drying may be performed after the development.

### [Silicon-Containing Film Pattern Forming Step]

In this step, the silicon-containing film is etched using the resist pattern as a mask to form a silicon-containing film pattern.

The above etching may be dry etching or wet etching, but dry etching is preferred.

Dry etching can be performed using, for example, a known dry etching apparatus. The etching gas used for dry etching can be appropriately selected according to the elemental composition of the silicon-containing film to be etched, and for example, fluorine-based gases such as CHF₃, CF₄, C₂F₆, C₃F₈ and SF₆, chlorine-based gases such as Cl₂ and BCl₃, oxygen-based gases such as 02, 03 and H₂O, reducing gases such as H₂, CO, CO₂, CH₄, C₂H₂, C₂H₄, C₂H₆, C₃H₄, C₃H₆, C₃H₈, HF, HI, HBr, HCl, NO and NH₃, and inert gases such as He, N₂ and Ar are used. These gases can also be mixed and used. For dry etching of a silicon-containing film, a fluorine-based gas is usually used, and a mixture of a fluorine-based gas, an oxygen-based gas and an inert gas is preferably used.

### [Etching Step]

In this step, etching is performed using the silicon-containing film pattern as a mask. More specifically, etching is performed one or more times using as a mask the pattern formed in the silicon-containing film obtained in the silicon-containing film pattern forming step to obtain a patterned substrate.

When an organic underlayer film is formed on the substrate, the organic underlayer film is etched using the silicon-containing film pattern as a mask to form a pattern of the organic underlayer film, and then the substrate is etched using this organic underlayer film pattern as a mask. Thus, a pattern is formed on the substrate.

The above etching may be dry etching or wet etching, but dry etching is preferred.

Dry etching for forming a pattern on the organic underlayer film can be performed using a known dry etching apparatus. The etching gas used for dry etching can be appropriately selected depending on the elemental composition of the silicon-containing film and the organic underlayer film to be etched. As the etching gas, the gas for etching the silicon-containing film described above can be suitably used, and these gases can also be mixed and used. An oxygen-based gas is usually used for dry etching of the organic underlayer film using the silicon-containing film pattern as a mask.

Dry etching for forming a pattern on the substrate using the organic underlayer film pattern as a mask can be performed using a known dry etching apparatus. The etching gas used for dry etching can be appropriately selected depending on the elemental composition of the organic underlayer film and the substrate to be etched, and the like. For example, etching gases similar to those exemplified as the etching gas used for the dry etching of the organic underlayer film may be used. Etching may be performed a plurality of times with different etching gases. After the etching step, if the silicon-containing film remains on the substrate, or on the resist underlayer pattern, etc., the silicon-containing film can be removed by performing the removing step described below.

### [Removing Step]

In this step, the silicon-containing film pattern is removed with a basic liquid. This step removes the silicon-containing film from the substrate. Also, the silicon-containing film residue after etching can be removed.

The basic liquid is not particularly limited as long as it is a basic solution containing a basic compound. Examples of basic compounds include sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, choline, 1,8-diazabicyclo[5.4.0]-7-undecene, 1,5-diazabicyclo[4.3.0]-5-nonene and the like. Among these, ammonia is preferable from the viewpoint of avoiding damage to the substrate.

From the viewpoint of further improving the removability of the silicon-containing film, the basic liquid is preferably a liquid containing a basic compound and water, or a liquid containing a basic compound, hydrogen peroxide and water.

The method for removing the silicon-containing film is not particularly limited as long as it is a method that allows the silicon-containing film and the basic liquid to come into contact with each other. Examples thereof include a method of immersing a substrate in a basic liquid, a method of spraying a basic liquid, a method of applying a basic liquid, and the like.

The temperature, time, and other conditions for removing the silicon-containing film are not particularly limited, and can be appropriately determined according to the film thickness of the silicon-containing film, the type of basic liquid used, and the like. The lower limit of the temperature is preferably 20° C., more preferably 40° C., and even more preferably 50° C. The upper limit of the temperature is preferably 300° C., more preferably 100° C. The lower limit of the time is preferably 5 seconds, more preferably 30 seconds. The upper limit of the time is preferably 10 minutes, more preferably 180 seconds.

In this step, washing and/or drying may be performed after removing the silicon-containing film.

### EXAMPLES

Hereinafter, Examples are described. The following Examples merely illustrate typical Examples of the present invention, and the Examples should not be construed to narrow the scope of the present invention.

In the present Examples, the weight-average molecular weight (Mw) of the compound (a) as an intermediate and the compound [A], the concentration of a solution of the compound [A], and the average thickness of a film were measured by the following methods.

### [Weight-Average Molecular Weight (Mw)]

The weight-average molecular weight (Mw) of compound (a-1) to compound (a-16) as the compound [a] and the compound [A] was measured by gel permeation chromatography (GPC) using GPC columns, available from Tosoh Corporation (“G2000HXL”×2, “G3000HXL”×1, and “G4000HXL”×1) under the following conditions.

Eluant: tetrahydrofuran (manufactured by Wako Pure Chemical Industries, Ltd.)

Flow rate: 1.0 mL/min

Sample concentration: 1.0% by mass

Sample injection amount: 100 μL

Column temperature: 40° C.

Detector: differential refractometer

Standard substance: monodisperse polystyrene

### [Concentration of Solution of Compound [A]]

The concentration (% by mass) of a solution of the compound [A] was calculated by firing 0.5 g of the solution of the compound [A] at 250° C. for 30 minutes, measuring a mass of a residue thus obtained, and dividing the mass of the residue by the mass of the solution of the compound [A].

### [Average Thickness of Film]

The average thickness of the film was measured by using a spectroscopic ellipsometer (“M2000D”, available from J. A. WOOLLAM CO.). More specifically, thicknesses of the film formed on a 12-inch silicon wafer were measured at optional nine points located at an interval of 5 cm including the center of the film, and the average value of the film thicknesses was calculated, and taken as the average thickness.

<Synthesis of Compounds (a-1) to (a-16)>

The monomers (hereinafter also referred to as “monomers (H-1), (H-2), (S-1) to (S-12)”) used for synthesis in Synthesis Examples 1 to 16 are shown below.

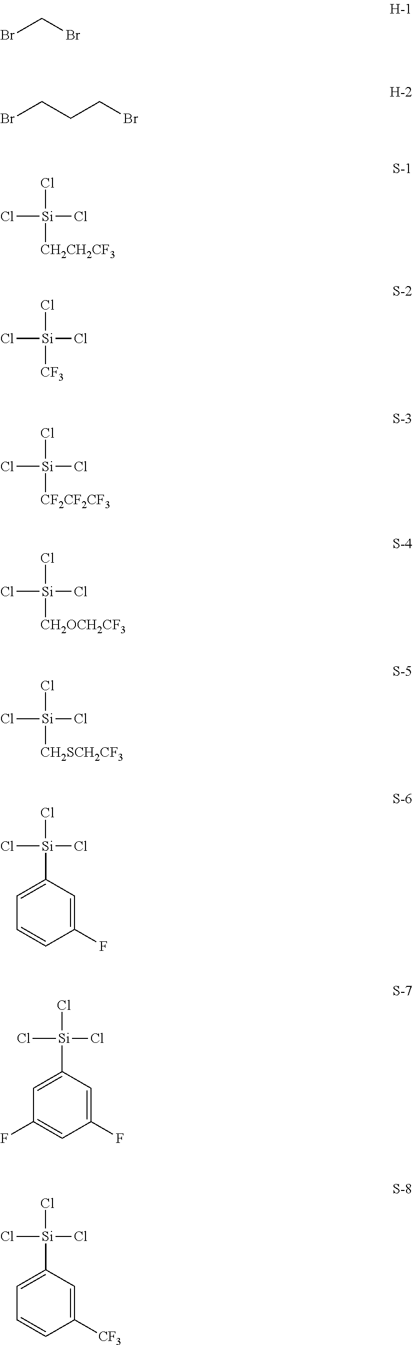

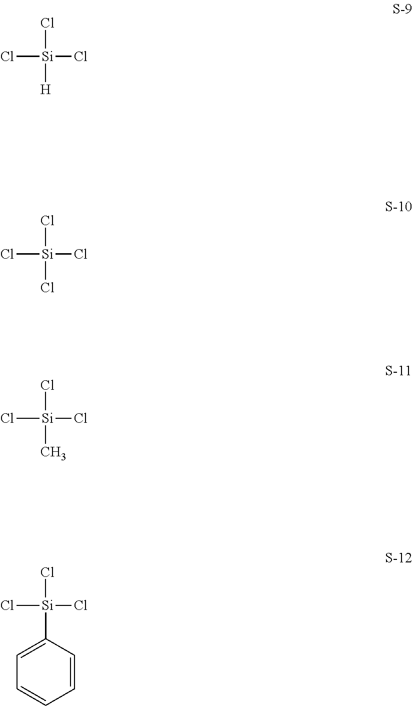

### [Synthesis Example 1-1] (Synthesis of Compound (a-1))

To a reaction vessel purged with nitrogen, 5.83 g of magnesium and 11.12 g of tetrahydrofuran were added, and the mixture was stirred at 20° C. Next, 17.38 g of monomer (H-1), 2.32 g of monomer (S-1), and 12.19 g of monomer (S-9) (molar ratio: 50/5/45 (mol %)) were dissolved in 111.15 g of tetrahydrofuran to prepare a monomer solution. The temperature in the reaction vessel was adjusted to 20° C., and the monomer solution was added dropwise thereto over 1 hour with stirring. A time point of completion of the dropwise addition was taken as a start time of a reaction, and the mixture was reacted at 40° C. for 1 hour and then at 60° C. for 3 hours. Then 66.69 g of tetrahydrofuran was added, and the mixture was cooled to 10° C. or lower, affording a polymerization reaction liquid. Subsequently, 30.36 g of triethylamine was added to the polymerization reaction liquid, and then 9.61 g of methanol was added dropwise thereto over 10 minutes with stirring. A time point of completion of the dropwise addition was taken as a start time of a reaction, and the mixture was reacted at 20° C. for 1 hour. Then the reaction liquid was charged into 220 g of diisopropyl ether, and the precipitated salt was filtered off. Next, tetrahydrofuran, diisopropyl ether, triethylamine, and methanol in the filtrate were removed using an evaporator. 50 g of diisopropyl ether was added to the residue obtained, the precipitated salt was filtered off, and diisopropyl ether was added to the filtrate, affording compound (a-1) having a concentration of 12% by mass. The Mw of compound (a-1) was 850.

### [Synthesis Examples 1-2 to 1-16] (Synthesis of Compounds (a-2) to (a-16))

Diisopropyl ether solutions of compounds (a-2) to (a-16) were obtained in the same manner as in Synthesis Example 1-1 except that the monomers of the types and use amounts shown in the following Table 1 were used, respectively. The Mw of the compounds (a) obtained is also disclosed in Table 1. “-” in Table 1 indicates that the corresponding monomer was not used.

TABLE 1

| | Compound | Charged amount of each monomer (mol %) | | | | | | | | | | | | | | Concentration | |
|---|---|---|---|---|---|---|---|---|---|---|---|---|---|---|---|---|---|
| | (a) | H-1 | H-2 | S-1 | S-2 | S-3 | S-4 | S-5 | S-6 | S-7 | S-8 | S-9 | S-10 | S-11 | S-12 | (% by mass) | Mw |
| Synthesis | a-1 | 50 | — | 5 | — | — | — | — | — | — | | 45 | — | — | — | 12 | 850 |
| Example | | | | | | | | | | | | | | | | | |
| 1-1 | | | | | | | | | | | | | | | | | |
| Synthesis | a-2 | 50 | — | 15 | — | — | — | — | — | — | — | 35 | — | — | — | 12 | 825 |
| Example | | | | | | | | | | | | | | | | | |
| 1-2 | | | | | | | | | | | | | | | | | |
| Synthesis | a-3 | 50 | — | 20 | — | — | — | — | — | — | — | 30 | — | — | — | 12 | 775 |
| Example | | | | | | | | | | | | | | | | | |
| 1-3 | | | | | | | | | | | | | | | | | |
| Synthesis | a-4 | 50 | — | 5 | — | — | — | — | — | — | — | — | 45 | — | — | 12 | 950 |
| Example | | | | | | | | | | | | | | | | | |
| 1-4 | | | | | | | | | | | | | | | | | |
| Synthesis | a-5 | 50 | — | 10 | — | — | — | — | — | — | — | 20 | 20 | — | — | 12 | 900 |
| Example | | | | | | | | | | | | | | | | | |
| 1-5 | | | | | | | | | | | | | | | | | |
| Synthesis | a-6 | — | 50 | 5 | — | — | — | — | — | — | — | 45 | — | — | — | 12 | 875 |
| Example | | | | | | | | | | | | | | | | | |
| 1-6 | | | | | | | | | | | | | | | | | |
| Synthesis | a-7 | 50 | — | — | 5 | — | — | — | — | — | — | 45 | — | — | — | 12 | 900 |
| Example | | | | | | | | | | | | | | | | | |
| 1-7 | | | | | | | | | | | | | | | | | |
| Synthesis | a-8 | 50 | — | — | — | 5 | — | — | — | — | — | 45 | — | — | — | 12 | 825 |
| Example | | | | | | | | | | | | | | | | | |
| 1-8 | | | | | | | | | | | | | | | | | |
| Synthesis | a-9 | 50 | — | — | — | — | 5 | — | — | — | — | 45 | — | — | — | 12 | 850 |
| Example | | | | | | | | | | | | | | | | | |
| 1-9 | | | | | | | | | | | | | | | | | |
| Synthesis | a-10 | 50 | — | — | — | — | — | 5 | — | — | — | 45 | — | — | — | 12 | 850 |
| Example | | | | | | | | | | | | | | | | | |
| 1-10 | | | | | | | | | | | | | | | | | |
| Synthesis | a-11 | 50 | — | — | — | — | — | — | 5 | — | — | 45 | — | — | — | 12 | 800 |
| Example | | | | | | | | | | | | | | | | | |
| 1-11 | | | | | | | | | | | | | | | | | |
| Synthesis | a-12 | 50 | — | — | — | — | — | — | — | 5 | — | 45 | — | — | — | 12 | 750 |
| Example | | | | | | | | | | | | | | | | | |
| 1-12 | | | | | | | | | | | | | | | | | |
| Synthesis | a-13 | 50 | — | — | — | — | — | — | — | — | 5 | 45 | — | — | — | 12 | 775 |
| Example | | | | | | | | | | | | | | | | | |
| 1-13 | | | | | | | | | | | | | | | | | |
| Synthesis | a-14 | 50 | — | — | — | — | — | — | — | — | — | 50 | — | — | — | 12 | 900 |
| Example | | | | | | | | | | | | | | | | | |
| 1-14 | | | | | | | | | | | | | | | | | |
| Synthesis | a-15 | 50 | — | — | — | — | — | — | — | — | — | 45 | — | 5 | — | 12 | 875 |
| Example | | | | | | | | | | | | | | | | | |
| 1-15 | | | | | | | | | | | | | | | | | |
| Synthesis | a-16 | 50 | — | — | — | — | — | — | — | — | — | 45 | — | — | 5 | 12 | 800 |
| Example | | | | | | | | | | | | | | | | | |
| 1-16 | | | | | | | | | | | | | | | | | |

### <Synthesis of Compound [A]>

The monomers (hereinafter also referred to as “monomers (M-1) to (M-4)”) used for synthesis in Synthesis Examples 2-1 to 2-23 are shown below. In addition, in the following Synthesis Examples 2-1 to 2-23, molo means a value taken when the total number of moles of silicon atoms in the compounds (a-1) to (a-16) used and the monomers (M-1) to (M-4) used is 100 mol %.

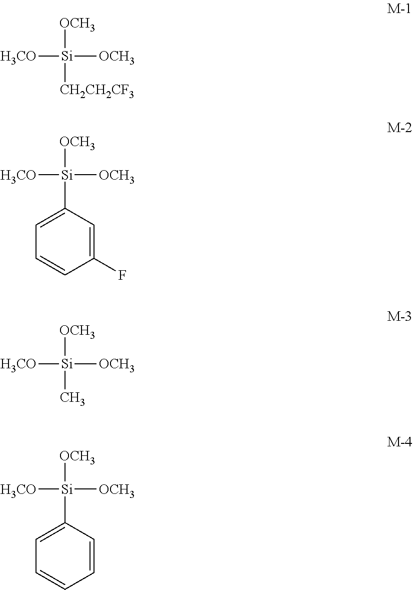

### [Synthesis Example 2-1] (Synthesis of Compound (A-1))

A reaction vessel was charged with 23.87 g of the diisopropyl ether solution of compound (a-1) obtained in Synthesis Example 1-1 and 24.29 g of acetone. The temperature in the reaction vessel was adjusted to 30° C., and 1.84 g of a 3.2% by mass aqueous solution of oxalic acid was added dropwise thereto over 20 minutes with stirring. A time point of completion of the dropwise addition was taken as a start time of a reaction, and the mixture was reacted at 40° C. for 4 hours. Then the inside of the reaction vessel was cooled to 30° C. or lower. Next, 25.0 g of diisopropyl ether and 150 g of water were added to this reaction vessel, and liquid separation extraction was performed. Thereafter, to the obtained organic layer was added 75 g of propylene glycol monomethyl ether acetate, and then water, acetone, diisopropyl ether, alcohols produced by the reaction, and excessive propylene glycol monomethyl ether acetate were removed using an evaporator. Subsequently, 5.0 g of trimethyl orthoformate as a dehydrating agent was added to the obtained solution, and the mixture was reacted at 40° C. for 1 hour, and then the inside of the reaction vessel was cooled to 30° C. or lower. Alcohols generated through the reaction, esters, trimethyl orthoformate, and excess propylene glycol monomethyl ether acetate were removed using the evaporator, affording a 5% by mass solution of compound (A-1) as the compound [A]. The Mw of compound (A-1) was 1,950.

### [Synthesis Examples 2-2 to 2-23] (Synthesis of Compounds (A-2) to (A-17) and (AJ-1) to (AJ-6))

Propylene glycol monoethyl ether solutions of compounds (A-2) to (A-17) and (AJ-1) to (AJ-6) as the compound [A] were obtained in the same manner as in Synthesis Example 2-1 except that the compounds and the monomers of the types and amounts shown in the following Table 2 were used. “-” in the columns of monomer in the following Table 2 indicates that the corresponding monomer was not used. The concentration (% by mass) of the obtained solution of the compound [A] and the Mw of the compound [A] are also shown in Table 2.

TABLE 2

| | Compound | Charged amount of compound and each monomer (Si mol %) | | | | | | Concentration | |
|---|---|---|---|---|---|---|---|---|---|
| | [A] | Compound | | M-1 | M-2 | M-3 | M-4 | (% by mass) | Mw |
| Synthesis | A-1 | a-1 | 100 | — | — | — | — | 5 | 1950 |
| Example 2-1 | | | | | | | | | |
| Synthesis | A-2 | a-2 | 100 | — | — | — | — | 5 | 1900 |
| Example 2-2 | | | | | | | | | |
| Synthesis | A-3 | a-3 | 100 | — | — | — | — | 5 | 1800 |
| Example 2-3 | | | | | | | | | |
| Synthesis | A-4 | a-4 | 100 | — | — | — | — | 5 | 2150 |
| Example 2-4 | | | | | | | | | |
| Synthesis | A-5 | a-5 | 100 | — | — | — | — | 5 | 2050 |
| Example 2-5 | | | | | | | | | |
| Synthesis | A-6 | a-6 | 100 | — | — | — | — | 5 | 2000 |
| Example 2-6 | | | | | | | | | |
| Synthesis | A-7 | a-7 | 100 | — | — | — | — | 5 | 2050 |
| Example 2-7 | | | | | | | | | |
| Synthesis | A-8 | a-8 | 100 | — | — | — | — | 5 | 1900 |
| Example 2-8 | | | | | | | | | |
| Synthesis | A-9 | a-9 | 100 | — | — | — | — | 5 | 1950 |
| Example 2-9 | | | | | | | | | |
| Synthesis | A-10 | a-10 | 100 | — | — | — | — | 5 | 1950 |
| Example 2-10 | | | | | | | | | |
| Synthesis | A-11 | a-11 | 100 | — | — | — | — | 5 | 1850 |
| Example 2-11 | | | | | | | | | |
| Synthesis | A-12 | a-12 | 100 | — | — | — | — | 5 | 1750 |
| Example 2-12 | | | | | | | | | |
| Synthesis | A-13 | a-13 | 100 | — | — | — | — | 5 | 1800 |
| Example 2-13 | | | | | | | | | |
| Synthesis | A-14 | a-14 | 90 | 10 | — | — | — | 5 | 1950 |
| Example 2-14 | | | | | | | | | |
| Synthesis | A-15 | a-14 | 70 | 30 | — | — | — | 5 | 1850 |
| Example 2-15 | | | | | | | | | |
| Synthesis | A-16 | a-14 | 60 | 40 | — | — | — | 5 | 1800 |
| Example 2-16 | | | | | | | | | |
| Synthesis | A-17 | a-14 | 90 | — | 10 | — | — | 5 | 1850 |
| Example 2-17 | | | | | | | | | |
| Synthesis | AJ-1 | a-14 | 100 | — | — | — | — | 5 | 2200 |
| Example 2-18 | | | | | | | | | |
| Synthesis | AJ-2 | a-15 | 100 | — | — | — | — | 5 | 2100 |
| Example 2-19 | | | | | | | | | |
| Synthesis | AJ-3 | a-16 | 100 | — | — | — | — | 5 | 1850 |
| Example 2-20 | | | | | | | | | |
| Synthesis | AJ-4 | a-14 | 90 | — | — | 10 | — | 5 | 2100 |
| Example 2-21 | | | | | | | | | |
| Synthesis | AJ-5 | a-14 | 90 | — | — | — | 10 | 5 | 1850 |
| Example 2-22 | | | | | | | | | |
| Synthesis | AJ-6 | — | — | 50 | — | 50 | — | 5 | 1800 |
| Example 2-23 | | | | | | | | | |

### <Preparation of Composition>

The components other than the compound [A] used for the preparation of compositions are shown below. In the following Examples 1-1 to 1-21 and Comparative Examples 1-1 and 1-6, unless otherwise specified, parts by mass represents a value taken when the total mass of components used is 100 parts by mass.

### [Solvent [B]]

B-1: Propylene glycol monomethyl ether acetate

### [Other Optional Component [C]]

C-1 (Acid generator): Compound represented by formula (C-1)

C-2 (Acid generator): Compound represented by formula (C-2)

C-3 (Basic compound): Compound represented by formula (C-3)

C-4 (Ortho ester): Trimethyl orthoformate

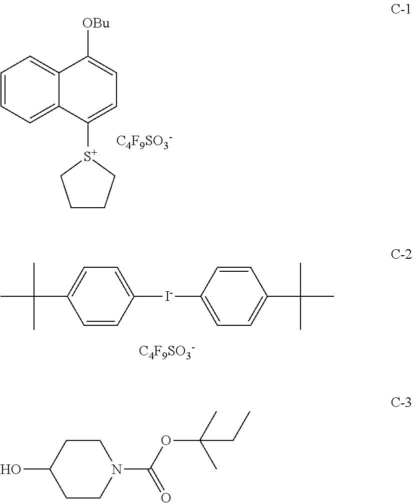

### [Example 1-1] (Preparation of Composition (J-1))

Composition (J-1) was prepared by mixing 1.00 part by mass of (A-1) (excluding the solvent) as the compound [A] and 99.00 parts by mass of (B-1) (including the solvent (B-1) contained in the solution of the compound [A]) as the solvent [B], and filtering the resulting solution through a filter having a pore size of 0.2 μm.

### [Examples 1-2 to 1-21, Comparative Examples 1-1 to 1-6](Preparation of Compositions (J-2) to (J-21) and (j-1) to (j-6))

Compositions (J-2) to (J-21) of Examples 1-2 to 1-21 and compositions (j-1) to (j-6) of Comparative Examples 1-1 to 1-6 were prepared in the same manner as in Example 1-1 except that respective components of types and blending amounts shown in the following Table 3 were used. “-” in the following Table 3 indicates that the corresponding component was not used.

### <Evaluation>

Using the compositions prepared as described above, resist pattern collapse inhibition property and film removability were evaluated by the following methods. The evaluation results are shown in the following Table 3.

<Preparation of Resist Composition for EUV Exposure>

A resist composition for EUV exposure (R-1) was obtained by mixing 100 parts by mass of a polymer having a structural unit (1) derived from 4-hydroxystyrene, a structural unit (2) derived from styrene, and a structural unit (3) derived from 4-t-butoxystyrene (content of each structural unit contained: (1)/(2)/(3)=65/5/30 (mol %)), 1.0 parts by mass of triphenylsulfonium trifluoromethanesulfonate as a radiation-sensitive acid generating agent, and 4,400 parts by mass of ethyl lactate and 1,900 parts by mass of propylene glycol monomethyl ether acetate each as a solvent, and filtering the obtained solution through a filter having a pore size of 0.2 μm.

### [Collapse Inhibition Property of Resist Pattern]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Limited), and thereafter heating was conducted at 250° C. for 60 sec to form an organic underlayer film having an average thickness of 100 nm. Each composition prepared as described above was applied on the organic underlayer film, and subjected to heating at 220° C. for 60 sec, followed by cooling at 23° C. for 30 sec to form a silicon-containing film having an average thickness of 20 nm. A resist composition for EUV exposure (R-1) was applied on each silicon-containing film formed as described above, and heating was conducted at 130° C. for 60 sec, followed by cooling at 23° C. for 30 sec to form a resist film having an average thickness of 50 nm. Next, the resist film was irradiated with extreme ultraviolet rays using an EUV scanner (“TWINSCAN NXE:3300B”, available from ASML Co. (NA=0.3; Sigma=0.9; quadrupole illumination, with a 1:1 line and space mask having a line width of 16 nm in terms of a dimension on wafer)). After the irradiation with the extreme ultraviolet rays, the substrate was heated at 110° C. for 60 sec, followed by cooling at 23° C. for 60 sec. Thereafter, development was performed by a paddle method using a 2.38% by mass aqueous tetramethylammonium hydroxide solution (20° C. to 25° C.), followed by washing with water and drying, thereby affording a substrate for evaluation having a resist pattern formed thereon. A scanning electron microscope (“SU8220” available from Hitachi High-Technologies Corporation) was used for length measurement and observation of the resist pattern of the substrate for evaluation. The collapse inhibition property of the resist pattern was evaluated as “A” (good) when collapse of a 1:1 line-and-space pattern having a line width of 16 nm in the substrate for evaluation was not confirmed, and evaluated as “B” (poor) when collapse of the resist pattern was confirmed.

[Film Removability after Etching Treatment]

Each of the compositions prepared as described above was applied to a 12-inch silicon wafer by a spin coating method using a spin coater (“CLEAN TRACK ACT12” available from Tokyo Electron Limited), heated at 220° C. for 60 seconds in the air atmosphere, and then cooled at 23° C. for 30 seconds, thereby forming a silicon-containing film having an average thickness of 20 nm. The substrate on which the silicon-containing film was formed was etched using an etching apparatus (“Tactras-Vigus” available from Tokyo Electron Limited) under the conditions of 02=400 sccm, PRESS.=25 mT, HF RF (high-frequency power for plasma generation)=200 W, LF RF (high-frequency power for bias)=0 W, DCS=0 V, RDC (gas center flow ratio)=50%, and 60 sec. Each of the substrates with a silicon-containing film resulting from the etching treatment was immersed in a removing liquid heated to 65° C. (25% by mass ammonia aqueous solution/30% by mass hydrogen peroxide water/water=1/1/5 (volume ratio) mixed aqueous solution) for 5 min, then washed with water, and dried to obtain a substrate for evaluation. In addition, each of the substrates with a silicon-containing film resulting from the etching treatment was immersed in a removing liquid heated to 65° C. (25% by mass ammonia aqueous solution/30% by mass hydrogen peroxide water/water=1/1/5 (volume ratio) mixed aqueous solution) for 10 min, then washed with water, and dried to obtain a substrate for evaluation. The cross section of each substrate for evaluation obtained as described above was observed using a field emission scanning electron microscope (“SU8220”, available from Hitachi High-Technologies Corporation), and evaluated as “A” (good) when the silicon-containing film did not remain in the case of the immersion of the substrate in the removing liquid for 5 min, “B” (slightly good) when the silicon-containing film remained in the case of the immersion of the substrate in the removing liquid for 5 min but the silicon-containing film did not remain in the case of the immersion of the substrate in the removing liquid for 10 min, and “C” (poor) when the silicon-containing film remained in the case of the immersion of the substrate in the removing liquid for 5 min and 10 min.

TABLE 3

| | | | | | | Other optional | | Pattern | |
|---|---|---|---|---|---|---|---|---|---|
| | | Compound [A] | | Solvent [B] | | component [C] | | collapse | |
| | | | Blending | | Blending | | Blending | inhibition | Film |
| | | | amount | | amount | | amount | property | removability |
| | | | (parts by | | (parts by | | (parts by | (EUV | after etching |
| | Composition | Type | mass) | Type | mass) | Type | mass) | exposure) | treatment |
| Example 1-1 | J-1 | A-1 | 1.00 | B-1 | 99.00 | — | — | A | A |
| Example 1-2 | J-2 | A-1 | 1.00 | B-1 | 95.97 | C-1/C-4 | 0.03/3.00 | A | A |
| Example 1-3 | J-3 | A-1 | 1.00 | B-1 | 98.97 | C-1 | 0.03 | A | A |
| Example 1-4 | J-4 | A-1 | 1.00 | B-1 | 98.97 | C-2 | 0.03 | A | A |
| Example 1-5 | J-5 | A-1 | 1.00 | B-1 | 98.97 | C-3 | 0.03 | A | A |
| Example 1-6 | J-6 | A-2 | 1.00 | B-1 | 99.00 | — | — | A | A |
| Example 1-7 | J-7 | A-3 | 1.00 | B-1 | 99.00 | — | — | A | A |
| Example 1-8 | J-8 | A-4 | 1.00 | B-1 | 99.00 | — | — | A | A |
| Example 1-9 | J-9 | A-5 | 1.00 | B-1 | 99.00 | — | — | A | A |
| Example 1-10 | J-10 | A-6 | 1.00 | B-1 | 99.00 | — | — | A | A |
| Example 1-11 | J-11 | A-7 | 1.00 | B-1 | 99.00 | — | — | A | A |
| Example 1-12 | J-12 | A-8 | 1.00 | B-1 | 99.00 | — | — | A | A |
| Example 1-13 | J-13 | A-9 | 1.00 | B-1 | 99.00 | — | — | A | A |
| Example 1-14 | J-14 | A-10 | 1.00 | B-1 | 99.00 | — | — | A | A |
| Example 1-15 | J-15 | A-11 | 1.00 | B-1 | 99.00 | — | — | A | A |
| Example 1-16 | J-16 | A-12 | 1.00 | B-1 | 99.00 | — | — | A | A |
| Example 1-17 | J-17 | A-13 | 1.00 | B-1 | 99.00 | — | — | A | A |
| Example 1-18 | J-18 | A-14 | 1.00 | B-1 | 99.00 | — | — | A | A |
| Example 1-19 | J-19 | A-15 | 1.00 | B-1 | 99.00 | — | — | A | A |
| Example 1-20 | J-20 | A-16 | 1.00 | B-1 | 99.00 | — | — | A | A |
| Example 1-21 | J-21 | A-17 | 1.00 | B-1 | 99.00 | — | — | A | A |
| Comparative | j-1 | AJ-1 | 1.00 | B-1 | 99.00 | — | — | B | C |
| Example 1-1 | | | | | | — | — | | |
| Comparative | j-2 | AJ-2 | 1.00 | B-1 | 99.00 | — | — | B | C |
| Example 1-2 | | | | | | — | — | | |
| Comparative | j-3 | AJ-3 | 1.00 | B-1 | 99.00 | — | — | B | B |
| Example 1-3 | | | | | | — | — | | |
| Comparative | j-4 | AJ-4 | 1.00 | B-1 | 99.00 | — | — | B | C |
| Example 1-4 | | | | | | — | — | | |
| Comparative | j-5 | AJ-5 | 1.00 | B-1 | 99.00 | — | — | B | B |
| Example 1-5 | | | | | | — | — | | |
| Comparative | j-6 | AJ-6 | 1.00 | B-1 | 99.00 | — | — | B | B |
| Example 1-6 | | | | | | — | — | | |

As is apparent from the results in Table 3, the silicon-containing films formed from the compositions of Examples could exhibit superior pattern collapse inhibition property and film removability as compared with the silicon-containing films formed from the compositions of Comparative Examples.

According to the composition and the method for manufacturing a semiconductor substrate of the present invention, a silicon-containing film superior in pattern collapse inhibition property and film removability can be formed. Therefore, these can be suitably used for manufacturing the semiconductor substrate and the like.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A composition comprising:
a compound comprising: at least one structural unit selected from the group consisting of a structural unit represented by formula (1-1) and a structural unit represented by formula (1-2); and a structural unit represented by formula (2-1); and
a solvent, 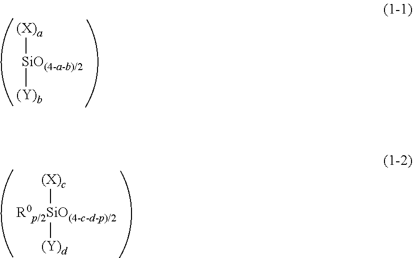
wherein
in the formula (1-1), X is a monovalent organic group other than an alkoxy group, the monovalent organic group having 1 to 20 carbon atoms and having at least one fluorine atom; a is an integer of 1 to 3; when a is 2 or more, the plurality of X's are the same or different from each other; Y is a monovalent organic group having 1 to 20 carbon atoms, a hydroxy group, or a halogen atom; b is an integer of 0 to 2; when b is 2, two Y's are the same or different from each other; and a+b is 3 or less,
in the formula (1-2), X is a monovalent organic group other than an alkoxy group, the monovalent organic group having 1 to 20 carbon atoms and having at least one fluorine atom; c is an integer of 1 to 3; when c is 2 or more, the plurality of X's are the same or different from each other; Y is a monovalent organic group having 1 to 20 carbon atoms, a hydroxy group, or a halogen atom; d is an integer of 0 to 2; when d is 2, two Y's are the same or different from each other; R⁰ is a substituted or unsubstituted divalent hydrocarbon group having 1 to 20 carbon atoms and bonded to two silicon atoms; p is an integer of 1 to 3; when p is 2 or more, the plurality of R⁰'s are the same or different from each other; and c+d+p is 4 or less, 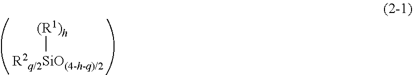
in the formula (2-1), R¹ is a monovalent organic group having 1 to 20 carbon atoms and having no fluorine atom, a hydroxy group, a hydrogen atom, or a halogen atom; h is 1 or 2; when h is 2, two R¹'s are the same or different from each other; R² is a substituted or unsubstituted divalent hydrocarbon group having 1 to 20 carbon atoms and bonded to two silicon atoms; q is an integer of 1 to 3; when q is 2 or more, the plurality of R²'s are the same or different from each other; provided that h+q is 4 or less.

2. The composition according to claim 1, wherein X's in the formula (1-1) and the formula (1-2) are each represented by formula (3),
*-L¹-Z-L²-R^{f} (3)
in the formula (3), L¹ and L² are each independently a single bond or a substituted or unsubstituted divalent hydrocarbon group having 1 to 10 carbon atoms; Z is a single bond, an oxygen atom, or a sulfur atom; R^{f} is a fluorine atom or a monovalent fluorinated hydrocarbon group having 1 to 10 carbon atoms; and * is a bond with the silicon atoms in the formula (1-1) and the formula (1-2).

3. The composition according to claim 1, wherein R⁰ in the formula (1-2) is a methanediyl group.

4. The composition according to claim 2, wherein R⁰ in the formula (1-2) is a methanediyl group.

5. The composition according to claim 1, wherein R² in the formula (2-1) is a methanediyl group.

6. The composition according to claim 2, wherein R² in the formula (2-1) is a methanediyl group.

7. The composition according to claim 3, wherein R² in the formula (2-1) is a methanediyl group.

8. The composition according to claim 4, wherein R² in the formula (2-1) is a methanediyl group.

9. The composition according to claim 1, wherein a total molar content of the structural unit represented by the formula (1-1) and the structural unit represented by the formula (1-2) in the compound relative to all structural units constituting the compound is 1 mol % or more and 50 mol % or less.

10. The composition according to claim 1 that is suitable for forming a resist underlayer film.

11. A method for manufacturing a semiconductor substrate, the method comprising:
applying the composition according to claim 1 directly or indirectly to a substrate to form a silicon-containing film;
applying a composition for forming a resist film directly or indirectly to the silicon-containing film to form a resist film;
exposing the resist film to radiation; and
developing the exposed resist film to form a resist pattern.

12. The method according to claim 11, further comprising forming an organic underlayer film directly or indirectly on the substrate before formation of the silicon-containing film.

13. The method according to claim 11, wherein the exposed resist film is developed with an alkaline developer.

14. The method according to claim 11, wherein X's in the formula (1-1) and the formula (1-2) are each represented by formula (3),
*-L¹-Z-L²-R^{f} (3)
in the formula (3), L¹ and L² are each independently a single bond or a substituted or unsubstituted divalent hydrocarbon group having 1 to 10 carbon atoms; Z is a single bond, an oxygen atom, or a sulfur atom; R^{f} is a fluorine atom or a monovalent fluorinated hydrocarbon group having 1 to 10 carbon atoms; and * is a bond with the silicon atoms in the formula (1-1) and the formula (1-2).

15. The method according to claim 11, wherein R⁰ in the formula (1-2) is a methanediyl group.

16. The method according to claim 14, wherein R⁰ in the formula (1-2) is a methanediyl group.

17. The composition according to claim 11, wherein R² in the formula (2-1) is a methanediyl group.

18. The composition according to claim 14, wherein R² in the formula (2-1) is a methanediyl group.

19. The composition according to claim 15, wherein R² in the formula (2-1) is a methanediyl group.

20. The composition according to claim 16, wherein R² in the formula (2-1) is a methanediyl group.
